(19) United States
(12) Patent Application Publication
(10) Pub. No.: US 2010/0314674 A1
(43) Pub. Date: Dec. 16, 2010

(54) SEMICONDUCTOR DEVICE AND METHOD FOR MANUFACTURING THE SAME

(75) Inventor: Toyonori ETOU, Tokyo (JP)

Correspondence Address: YOUNG & THOMPSON, 209 Madison Street, Suite 500, Alexandria, VA, 22314, US

(73) Assignee: ELPIDA MEMORY, INC, Tokyo (JP)

(21) Appl. No.: 12/783,189

(22) Filed: May 19, 2010

(30) Foreign Application Priority Data
Jun. 15, 2009 (JP) 2009-142512

(51) Int. Cl. H01L 27/108; H01L 21/02

(52) U.S. Cl. 257/296; 438/396; 257/E27.084; 257/E21.008

(57) ABSTRACT

A semiconductor device includes a semiconductor chip including an interlayer insulating film, a first area, and a first crack stopper. The first area includes a plurality of capacitors, each of which includes a lower electrode and a dielectric film sequentially formed on the inner wall of a first opening and an upper electrode buried in the first opening, and a plate electrode provided to be electrically connected to the upper electrode of each of the capacitors. The first crack stopper includes first and second films sequentially formed on the inner wall of a second opening, a third film buried in the second opening, and an upper area provided to be in contact with the third film.

This application is based upon and claims the benefit of priority from Japanese Patent Application No. 2009-142512, filed on Jun. 15, 2009, the disclosure of which is incorporated herein in its entirety by reference.

### BACKGROUND OF THE INVENTION

1. Field of the Invention

The present invention relates to a semiconductor device and a method for manufacturing the same.

2. Description of the Related Art

To reduce manufacturing cost of a semiconductor device, there has been a method for increasing the number of chips to be acquired per wafer by the size reduction of a chip.

FIGS. 1 to 12 show a conventional method for manufacturing a semiconductor device. First, isolation regions, transistors, and other components (none of them are shown) are formed in a semiconductor substrate. An interlayer insulating film, contact plugs, and other components (none of them are shown) are formed on the semiconductor substrate.

Silicon nitride film 1, which will function as an etching stopper when capacitor cylinders are processed, is formed on the interlayer insulating film. Silicon oxide film 2 as an interlayer insulating film is deposited on silicon nitride film 1.

Silicon oxide film 2 may be replaced with a plurality of films formed in a deposition step depending on process conditions. Examples of the plurality of films may include TEOS-non-doped silicate glass, silane-non-doped silicate glass, and boron/phosphorus-doped silicate glass (BPSG). Further, silicon nitride film 3 as an upper end support, may further be deposited on silicon oxide film 2 to prevent the capacitor cylinders from collapsing when the size of a DRAM is reduced. The present example is described with reference to a case where silicon nitride film 3 is deposited on silicon oxide film 2. FIG. 1 shows this state.

Lithography is used to provide cylinder holes 4 passing through silicon oxide film 2 in the thickness direction thereof and provide opening 5 that surrounds cylinder holes 4. FIG. 2 is a top view showing this state, and FIG. 3 is a cross-sectional view taken along line A-A′ in FIG. 2. Each of cylinder holes 4 is formed by using silicon nitride film 1 as an etching stopper film and forming holes through silicon oxide film 2.

CVD is used to form lower electrode film 6 over the surface of the interlayer insulating film 2. As lower electrode film 6, for example, a titanium nitride film can be deposited. Thereafter, cylinder holes 4 and opening 5 are filled with photoresist material 7, and then lower electrode film 6 on silicon nitride film 3 is removed in an etchback step. As a result, lower electrode 6 is formed on the inner wall of each of cylinder holes 4, and conductive film 6 is formed on the inner wall of opening 5. FIG. 4 is a top view showing this state, and FIG. 5 is a cross-sectional view taken along line A-A′ in FIG. 4.

Lithography is used to provide openings 8 for wet etching in silicon nitride film 3. FIG. 6 is a top view showing this state.

Silicon nitride film 3 and photoresist material 7 are used as a mask to perform hydrofluoric acid-based wet etching. The wet etching removes silicon oxide film 2 and exposes the outer side surfaces of lower electrodes 6. FIG. 7 is a top view showing this state, and FIG. 8 is a cross-sectional view taken along line A-A′ in FIG. 7. Photoresist material 7 may be removed after lower electrode film 6 on silicon nitride film 3 is removed. In this case, the wet etching removes silicon oxide film 2 with no photoresist material 7 present in cylinder holes 4.

The portion of silicon oxide film 2 that is not desired to be wet-etched can be coated and covered with lower electrode film 6 and silicon nitride films 1 and 3 above and below lower electrode film 6 so that the portion will not be etched. After photoresist material 7 in cylinder holes 4 and opening 5 is removed, capacitor capacitive film 9 is deposited over the surface of the resulting structure (FIG. 9). A conductor film is then deposited over the surface to form upper electrode 12 in each of cylinder holes 4, and plate electrode 10 is formed on silicon nitride film 3. Thereafter, plate electrode 11 is further formed on plate electrode 10. Lower electrode 6, capacitor capacitive film 9, and upper electrode 12 form a capacitor having a crown structure.

Lithography is used to leave capacitor capacitive film 9 and plate electrodes 10 and 11 only in a predetermined area on silicon nitride film 3. FIG. 10 is a cross-sectional view showing this state.

Polysilicon film can be used as the plate conductive film 10. Filling the space between the capacitors with polysilicon film 10 prevents the capacitors from collapsing. Plate conductive film 11 can be a W film (Tungsten film) formed by sputtering. W film 11 can enhance the conductivity between the plate electrode and, for example, an upper layer wiring structure provided above the plate electrode.

Interlayer insulating film 2 and the upper layer wiring structure (not shown) are formed on silicon nitride film 3 and plate electrode 11. Thereafter, die seal rings 13 are formed in such a way that they pass through interlayer insulating film 2 in the thickness direction thereof and extend from the upper end of interlayer insulating film 2 to a portion below interlayer insulating film 2. FIG. 11 is a cross-sectional view showing this state.

A wafer on which semiconductor chips are formed is thus completed. The wafer is diced into individual semiconductor chips. In FIG. 11, the dicing is carried out along area 30 indicated by the corresponding arrow, and area 31 forms a circuit area.

FIG. 12 shows how the wafer is diced into the individual semiconductor chips. In FIG. 12, the dotted lines represent the die seal rings, and the portion surrounded by each of the die seal rings represents the circuit area. The area between the portions surrounded by the dotted lines corresponds to area 30 in FIG. 11. The individual semiconductor chips can be produced by dicing the wafer along area 30 into the semiconductor chips.

JP11-74229 discloses a semiconductor device having a dummy pattern that is substantially the same as an upper gate electrode formed in the area corresponding to a dicing line so that crack chippings produced due to cracking at the time of dicing can be reduced in size.

JP2001-23937 discloses a semiconductor device provided with a barrier wall, a sacrificial compound structure, and a slot structure along chip edges on both sides of a dicing line in order to prevent a crack from propagating when a wafer is divided into chips.

JP2005-167198 discloses a semiconductor device including a die seal ring which passes through a laminate structure formed of interlayer insulating films around a chip area and seamlessly surrounds the chip area, and which prevents a crack produced at the time of dicing from reaching the chip area.

### SUMMARY OF THE INVENTION

In one embodiment, there is provided a semiconductor device comprising:

an interlayer insulating film;

a first area provided in the interlayer insulating film; and

a first crack stopper provided in the interlayer insulating film and surrounding the first area,

wherein the first area includes:

a plurality of capacitors, each of the capacitors including a lower electrode and a dielectric film sequentially formed on the inner wall of a first opening passing through the interlayer insulating film in the thickness direction thereof; and

an upper electrode buried in the first opening in such a way that the upper electrode is in contact with the dielectric film, and

the first crack stopper includes:

a first film and a second film sequentially formed on the inner wall of a second opening surrounding the first area and passing through the interlayer insulating film in the thickness direction thereof; and

a third film buried in the second opening in such a way that the third film covers the second opening and is in contact with the second film,

wherein the first film is made of the same material as the lower electrode, and the second film is made of the same material as the dielectric film, and the third film is made of the same material as the upper electrode. In another embodiment, there is provided a method for manufacturing a semiconductor device, the method comprising:

preparing a wafer including an interlayer insulating film including a first area;

simultaneously forming a first opening passing through the interlayer insulating film in the first area in the thickness direction thereof, and a second opening surrounding the first area and passing through the interlayer insulating film in the thickness direction thereof;

simultaneously forming a lower electrode on the inner wall of the first opening and a first film on the inner wall of the second opening;

removing the interlayer insulating film in the first area surrounding the first opening;

simultaneously forming a dielectric film on the lower electrode in the first opening and a second film on the first film in the second opening;

simultaneously forming an upper electrode on the dielectric film and a third film on the second film, the third film covering the second opening; and

dicing the wafer at a dicing area to get a plurality of semiconductor chips,

wherein the second opening is formed at a border area between the dicing area and the first area.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 12 describe a related method for manufacturing a semiconductor device;

FIGS. 13 to 26 describe a method for manufacturing a semiconductor device according to a first exemplary embodiment;

FIGS. 27 to 29 describe a semiconductor device according to a second exemplary embodiment; and

FIG. 30 describes a semiconductor device according to a third exemplary embodiment.

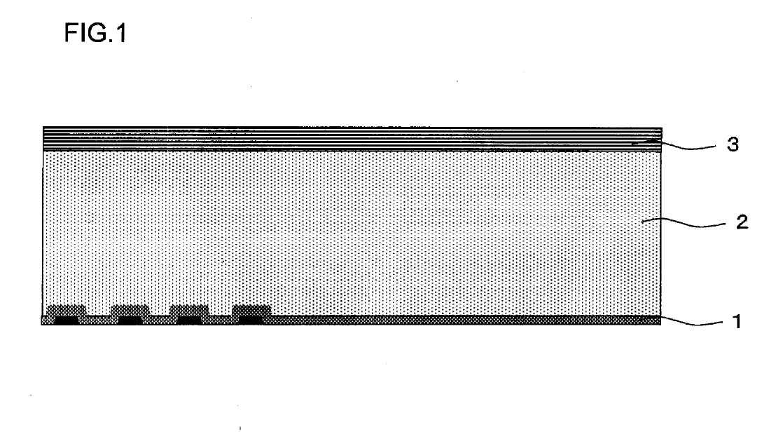

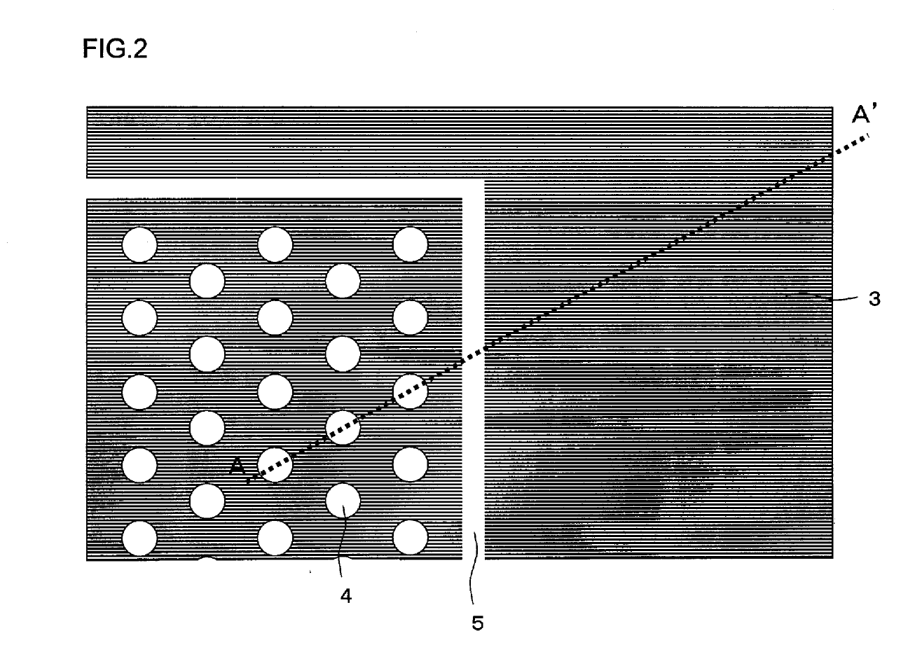

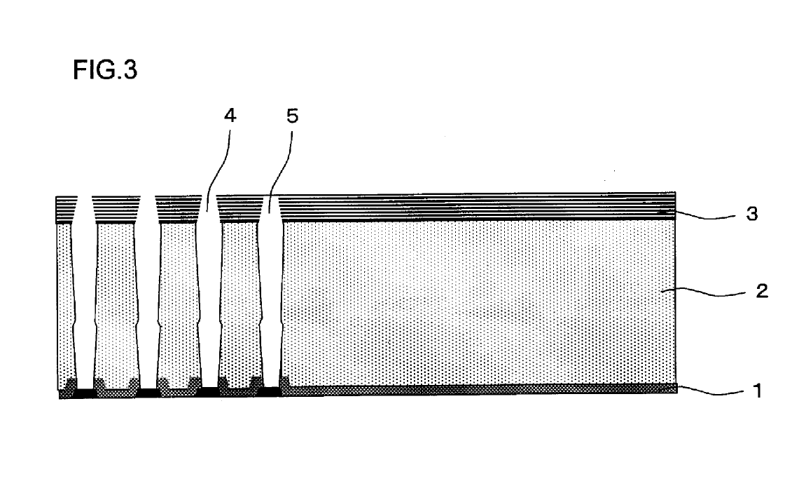

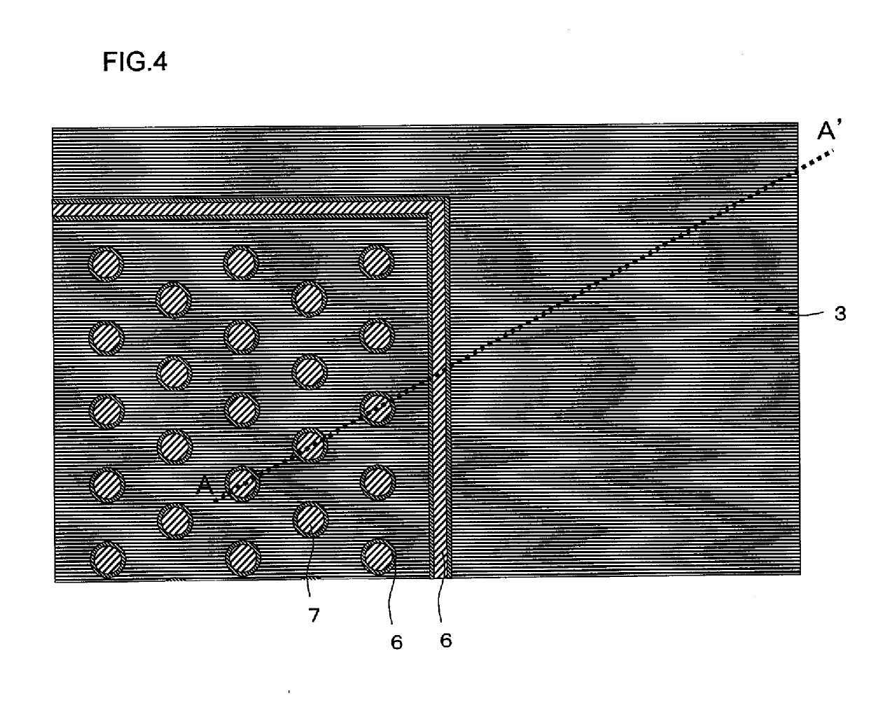

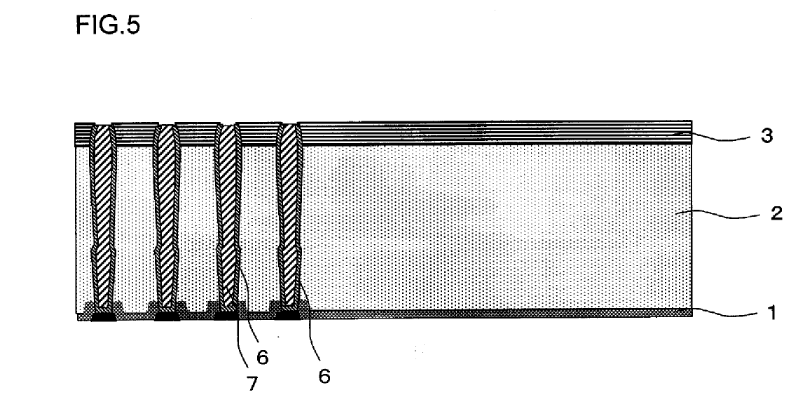

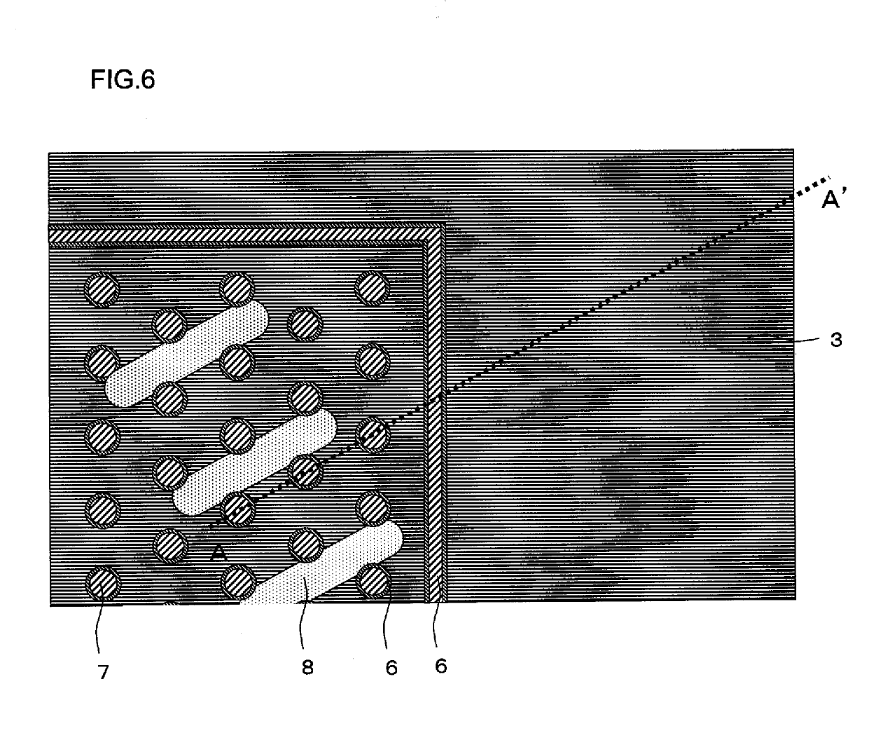

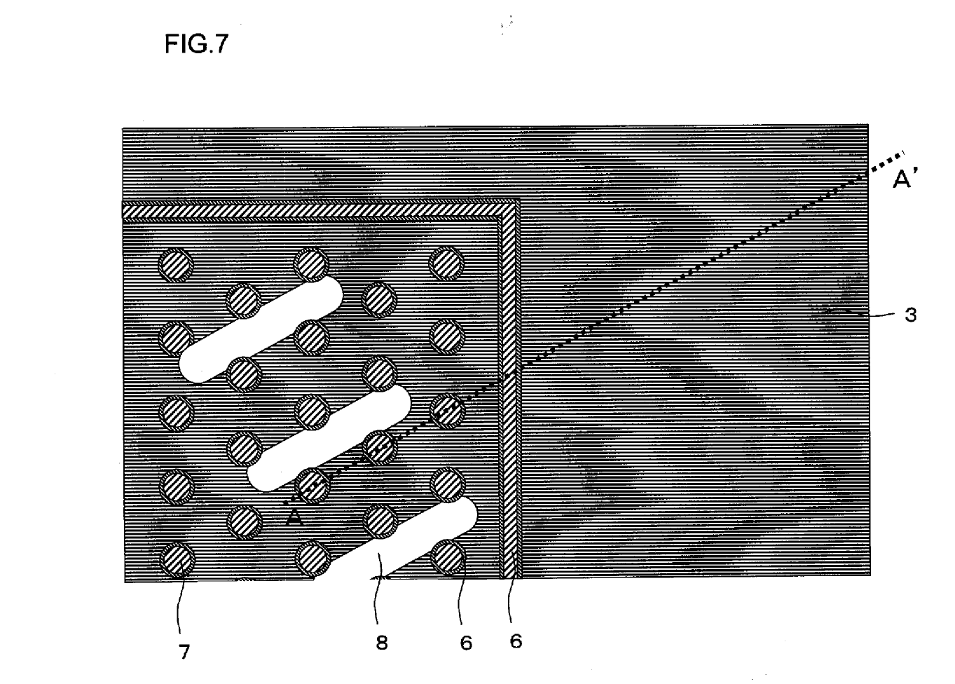

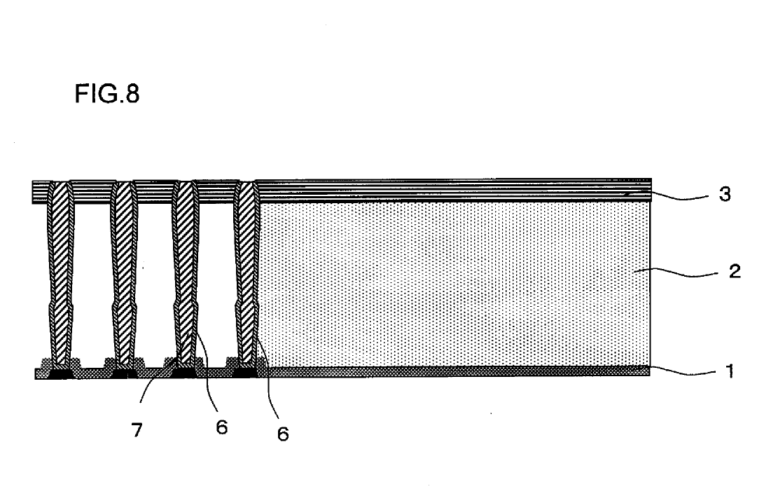

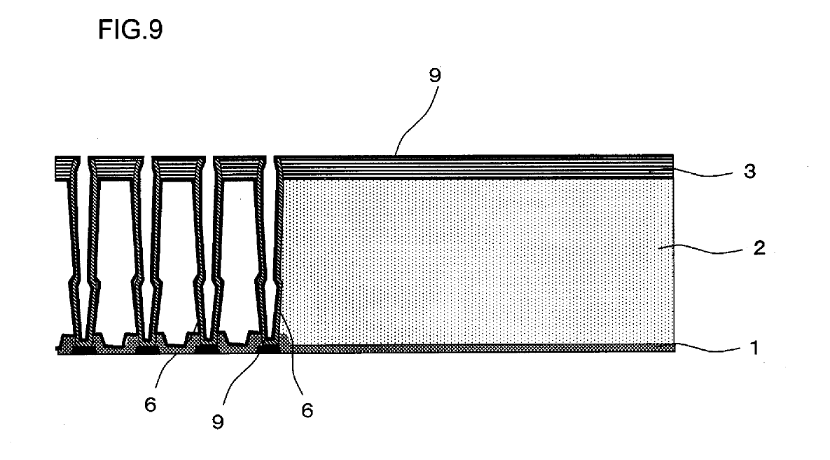

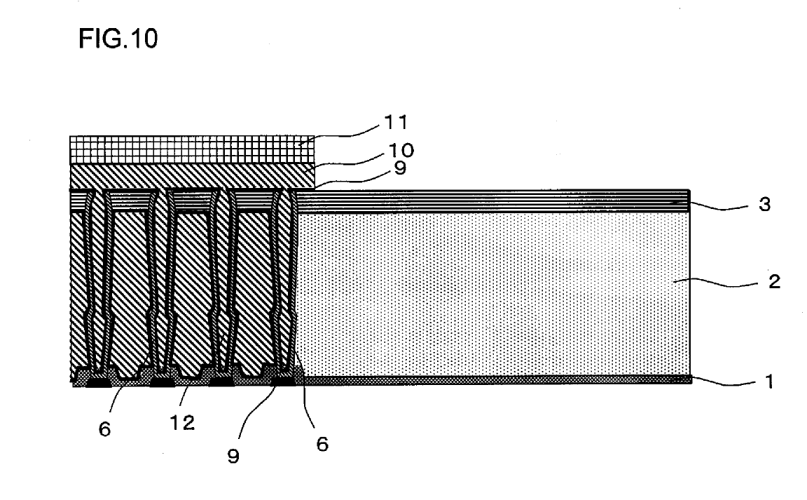

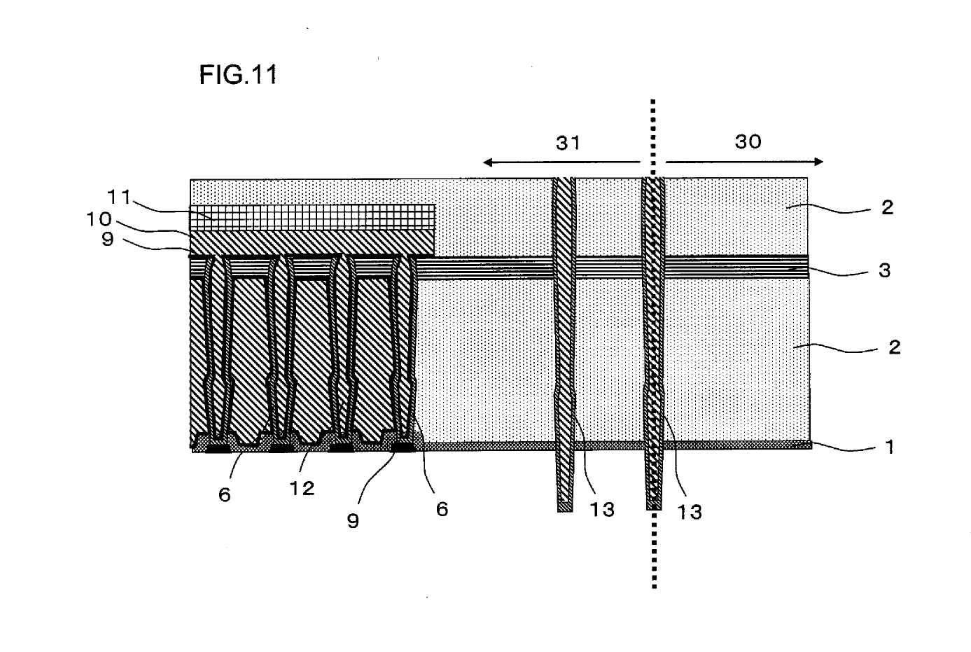

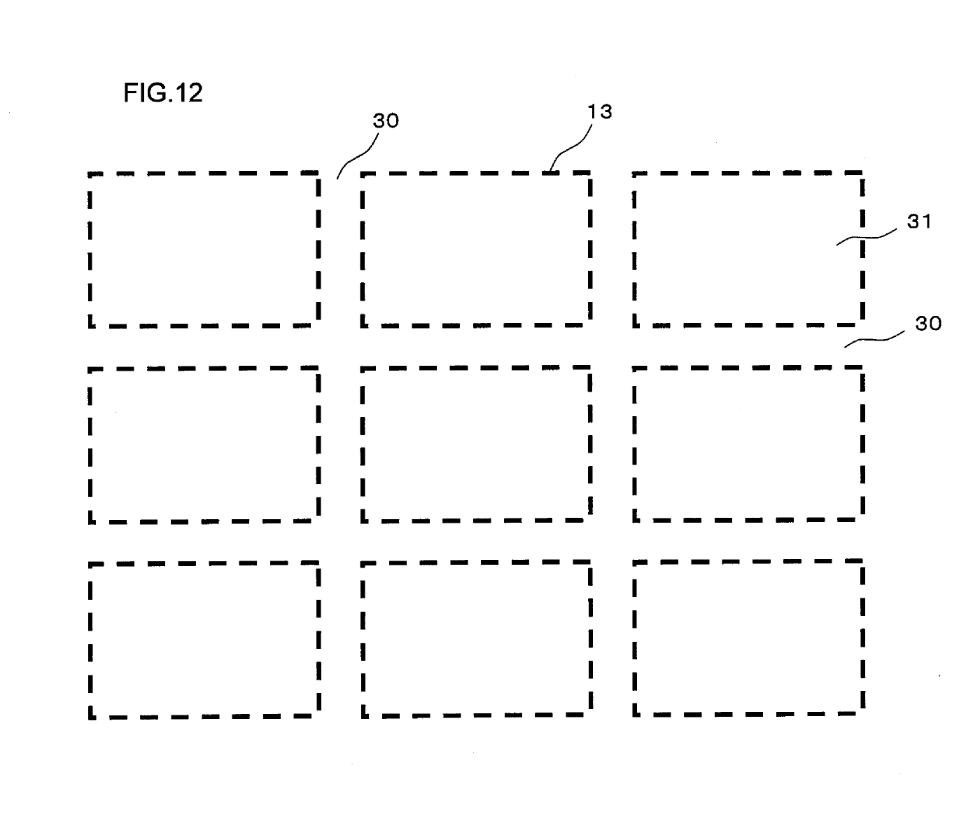

In the drawings, numerals have the following meanings. 1: silicon nitride film, 2: silicon oxide film, 3: silicon nitride film, 4: cylinder hole, 5: opening, 6: lower electrode, 6a: first film, 7: photoresist, 8: opening, 9: capacitor capacitive film, 9a: second film, 10, 11: plate electrode, 10a, 11a: upper area, 12: upper electrode, 12a: third film, 13: die seal ring, 16: crack, 17: opening for stopping cracks, 18: crack stopper, 19: cavity, 21a, 21b: contact plug, 22: gate electrode, 23: source/drain regions, 24: semiconductor substrate, 25: interlayer insulating film, 26: bit wiring line, 28: isolation region, 29: gate insulating film, 30: dicing area, 31: circuit area.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

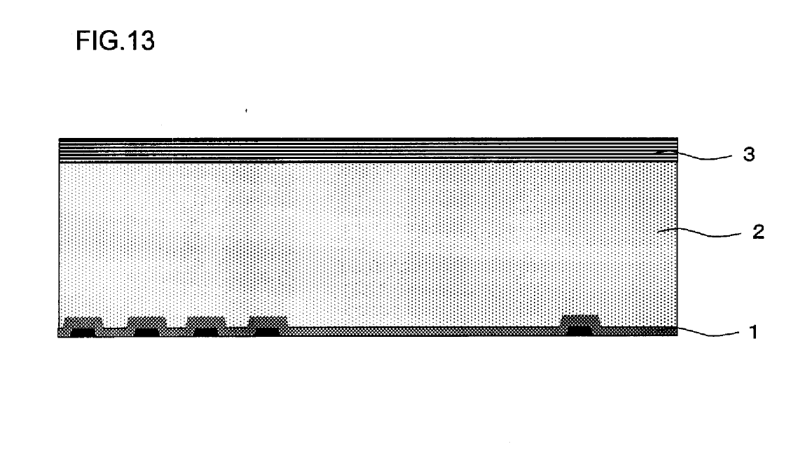

FIGS. 13 to 26 show the method for manufacturing a semiconductor device according to the present exemplary embodiment. After a lower structure (not shown) is formed, silicon nitride film 1, silicon oxide film 2 as an interlayer insulating film, and silicon nitride film 3 were sequentially formed. FIG. 13 is a cross-sectional view showing this state.

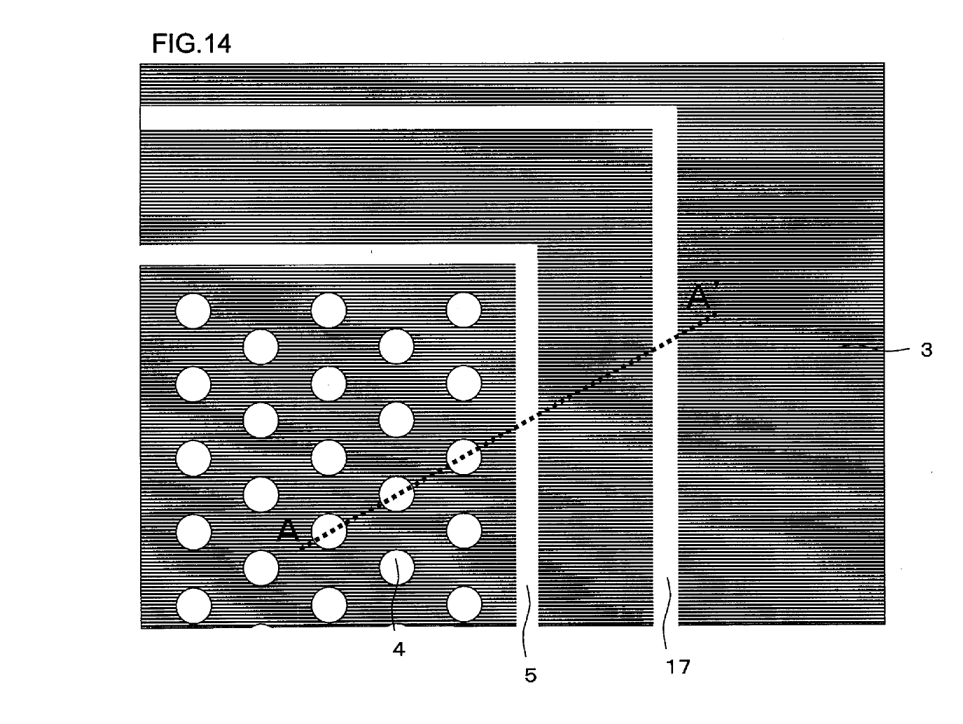

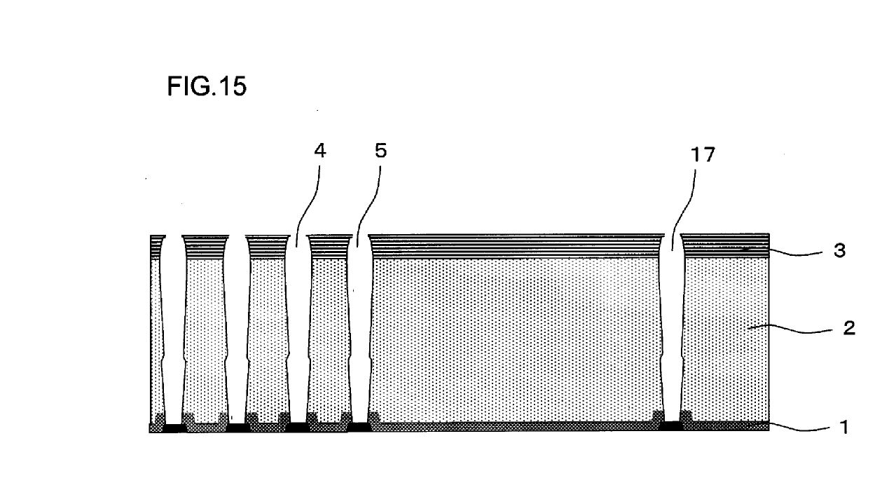

Lithography was used to provide a mask pattern in silicon nitride film 3. Silicon nitride film 3 was used as a mask to etch silicon oxide film 2 so that cylinder holes 4 (corresponding to first openings) for capacitors, opening 5, and opening 17 (corresponding to second opening) for stopping cracks were simultaneously formed. Opening 5 and opening 17 for stopping cracks were formed in such a way that they seamlessly surrounded cylinder holes 4. FIG. 14 is a top view showing this state, and FIG. 15 is a cross-sectional view taken along line A-A′ in FIG. 14. FIG. 14 shows part of cylinder holes 4, openings 5 and 17.

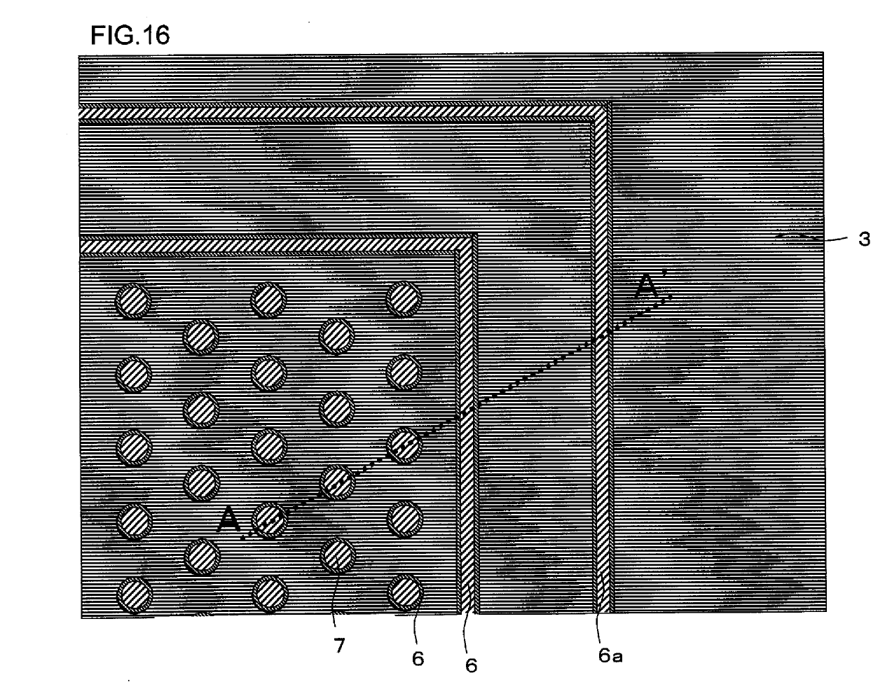

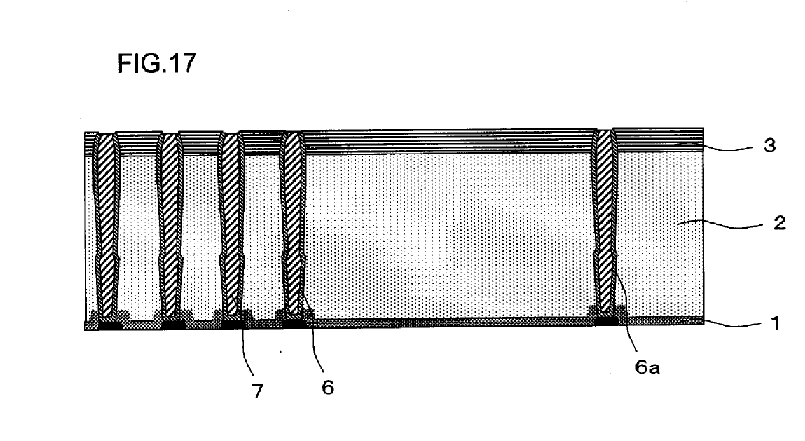

CVD was used to form lower electrode films 6 and 6a over the surface of the resulting structure. In the present exemplary embodiment, a titanium nitride film was deposited as lower electrode films 6 and 6a. Thereafter, cylinder holes 4, opening 5 and opening 17 were filled with photoresist material 7, and then lower electrode film 6 on silicon nitride film 3 was removed in an etchback step. As a result, not only was lower electrode 6 formed on the inner wall of each of cylinder holes 4, but also film 6 was formed on the inner wall of opening 5 and first film 6a was formed on the inner wall of opening 17 for stopping cracks. FIG. 16 is a top view showing this state, and FIG. 17 is a cross-sectional view taken along line A-A′ in FIG. 16.

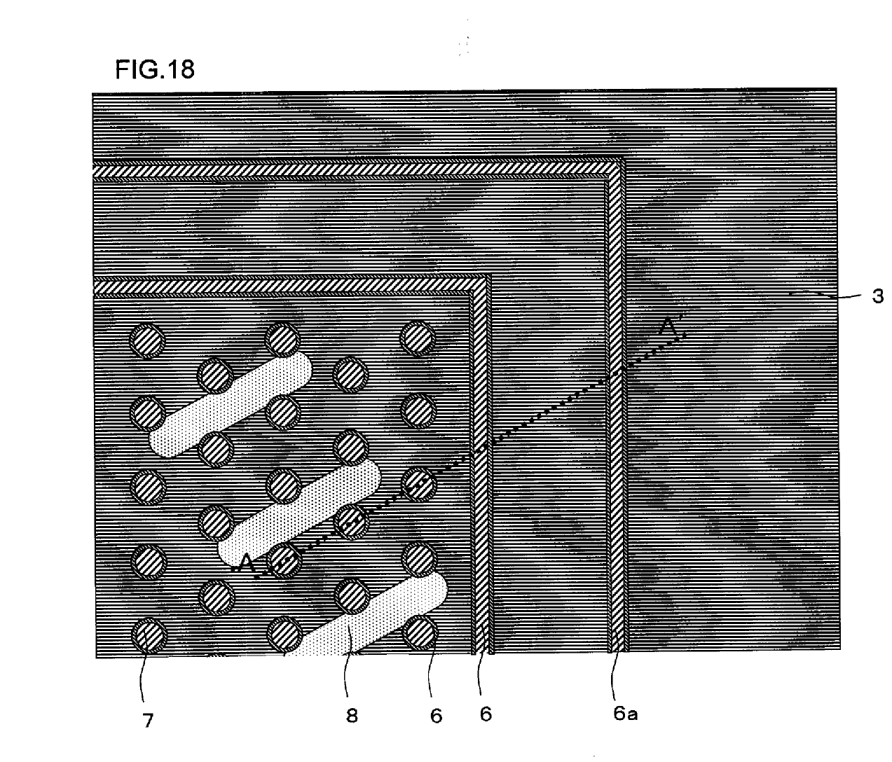

Lithography was used to provide openings 8 for wet etching in silicon nitride film 3. FIG. 18 is a top view showing this state.

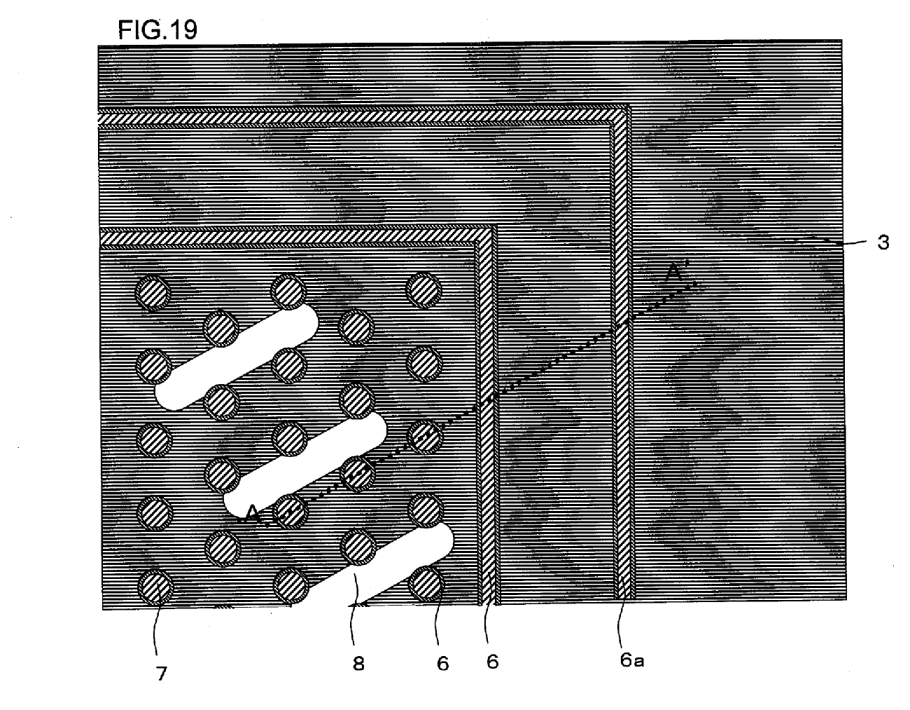

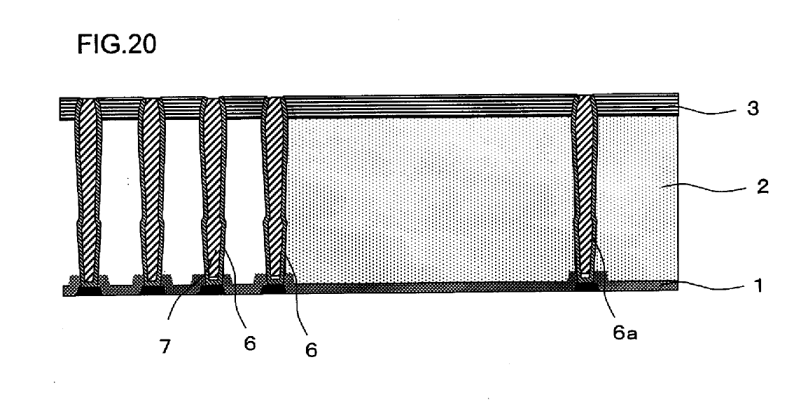

Silicon nitride film 3 and photoresist material 7 were used as a mask to perform hydrofluoric acid-based wet etching. The wet etching removed silicon oxide film 2 and exposed the outer side surfaces of lower electrodes 6. In this process, the area of silicon oxide film 2 that was surrounded by openings 5 and 17 and silicon nitride film 3 were not removed but left because the area was not exposed to the hydrofluoric acid at the time of wet etching. FIG. 19 is a top view showing this state, and FIG. 20 is a cross-sectional view taken along line A-A′ in FIG. 19. Photoresist material 7 may be removed after lower electrode film 6 on silicon nitride film 3 was removed. In this case, the wet etching removed silicon oxide film 2 with no photoresist material 7 filled in cylinder holes 4.

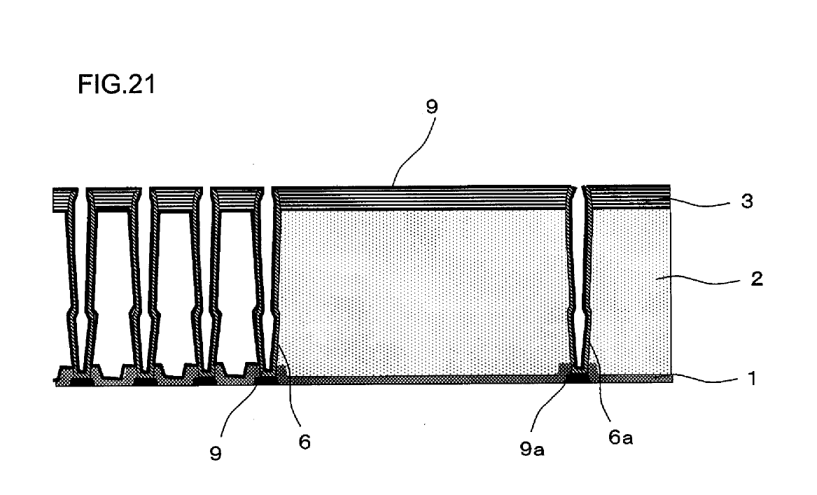

After photoresist material 7 in cylinder holes 4, opening 5 and opening 17 were removed, capacitor capacitive film 9 was deposited over the surface of the resulting structure (FIG. 21). In this process, capacitor capacitive film 9 (corresponding to a dielectric film) was formed in such a way that it came into contact with lower electrodes 6 in cylinder holes 4, and film 9a (corresponding to a second film) was formed in opening 17 for stopping cracks at the same time.

Conductive film 10 was then deposited over the surface of the resulting structure. The deposition caused each of cylinder holes 4 to be filled with upper electrode 12 and opening 17 for stopping cracks to be filled with a conductive film (corresponding to a third film). Conductive film 10 was also formed over the surface of the silicon nitride film. In this process, the space between capacitors was filled with conductive film 10. In the present exemplary embodiment, polysilicon film was used as conductive film 10. Filling the space between the capacitors with polysilicon film 10 prevented the capacitors from collapsing. A laminate film including a TiN film and a polysilicon film may be used for conductive film 10.

Conductive film 11 was further deposited over the surface of polysilicon film 10. In the present exemplary embodiment, conductive film 11 was a W film formed by sputtering. W film 11 can enhance the conductivity between polysilicon film 10 and, for example, an upper layer wiring structure provided above polysilicon film 10.

Carrying out the steps described above allowed the capacitors, each of which included a crown structure formed of lower electrode 6, dielectric film 9, and upper electrode 12, to be formed. At the same time, part of the structure of each first crack stopper formed of first film 6a, second film 9a, and third film 12a was formed.

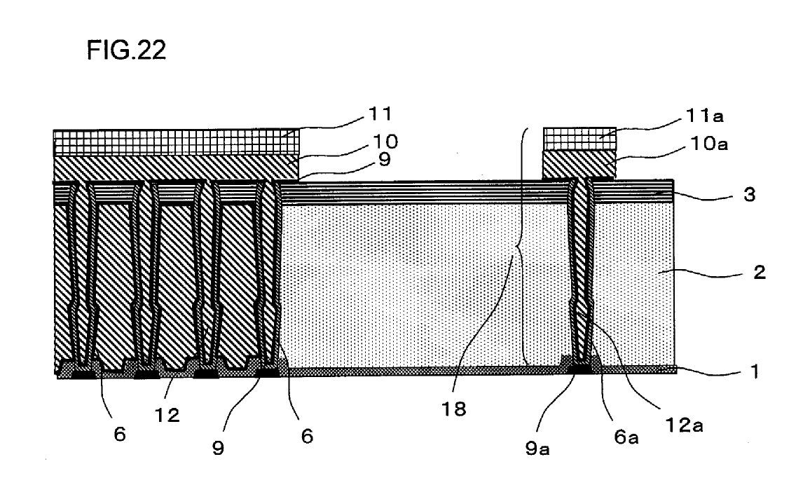

Lithography was then used to remove polysilicon film 10 and W film 11 in such a way that polysilicon film 10 and W film 11 were left only on the capacitors and the partial structure of each first crack stopper. A plate electrode formed of polysilicon film 10 and W film 11 was thus formed on the capacitors. At the same time, each first crack stopper 18 formed of first film 6a, second film 9a, third film 12a, and upper areas 10a and 11a was formed. FIG. 22 is a cross-sectional view showing this state.

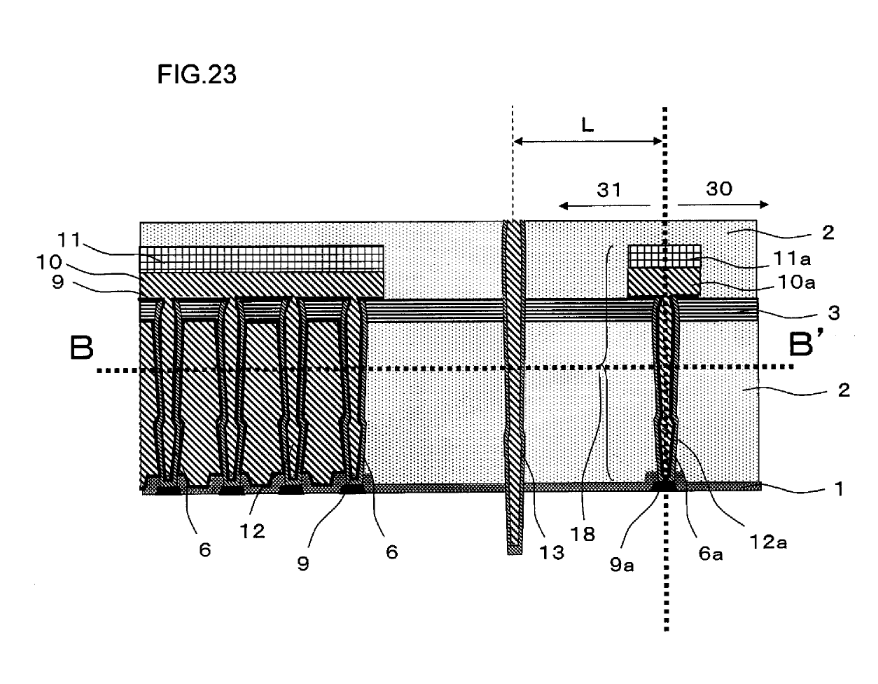

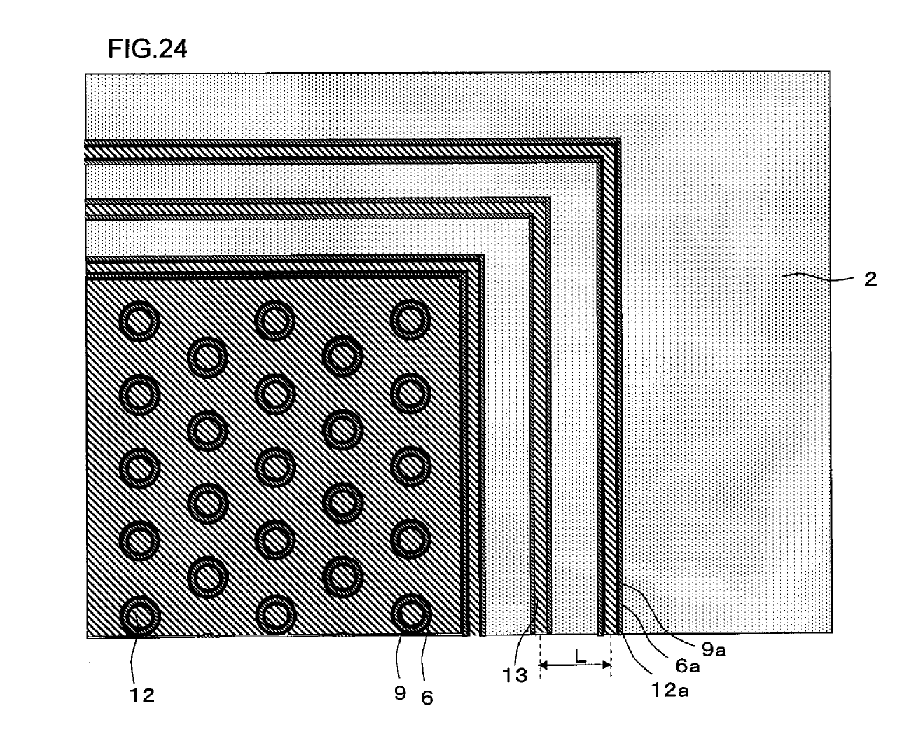

Interlayer insulating film 2 and the upper layer wiring structure (not shown) are formed over silicon nitride film 3. Thereafter, die seal rings 13 extending from a portion over silicon nitride film 3 to a portion below silicon nitride film 1 were formed. Die seal rings 13 can be formed for example, by forming contact holes and filling the contact holes with metal plugs. FIG. 23 is a cross-sectional view showing this state, and FIG. 24 is a cross-sectional view taken along line B-B′ in FIG. 23. A wafer with semiconductor chips was thus completed. In FIG. 23, dicing was carried out along area 30 indicated by the corresponding arrow, and area 31 forms a circuit area corresponding to a first area. In FIG. 24, the area surrounded by each crack stopper 18 forms the circuit area and corresponds to the first area. FIG. 24 shows part of the first area.

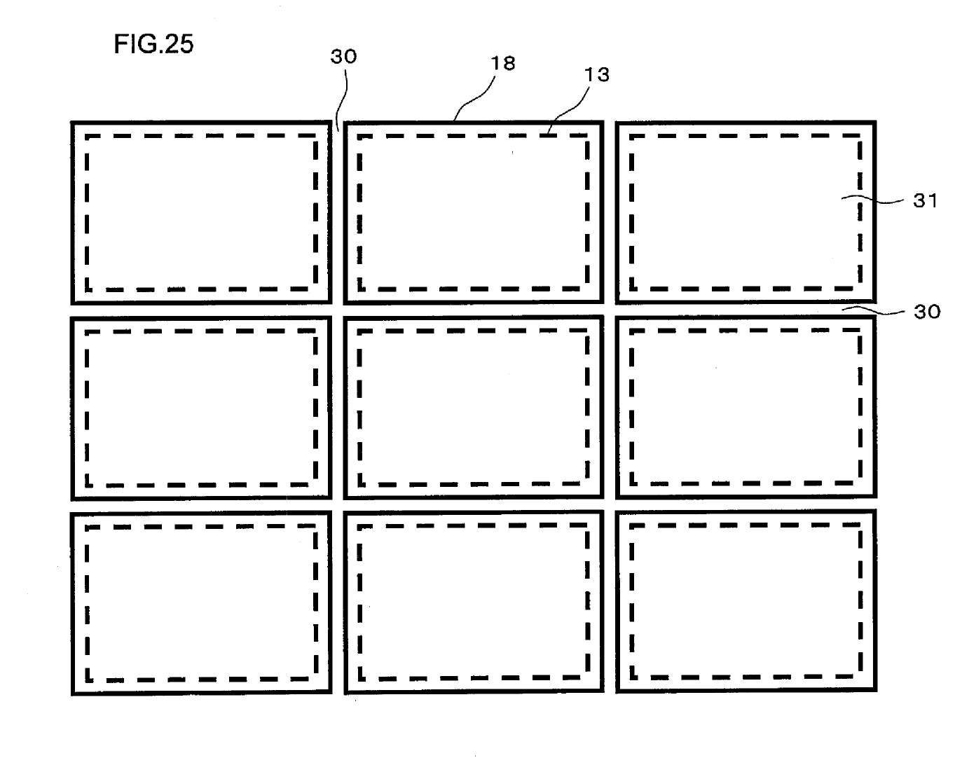

The wafer was diced into individual semiconductor chips. FIG. 25 shows how the wafer is diced into semiconductor chips. In FIG. 25, dotted lines 13 represent the die seal rings and the solid lines represent first crack stoppers 18. The area surrounded by each of the first crack stoppers represents the circuit area and corresponds to area 31 (first area) in FIG. 23. The area between the portions surrounded by the solid lines corresponds to area 30 in FIG. 23. The individual semiconductor chips can be produced by dicing the wafer along area 30 into the semiconductor chips.

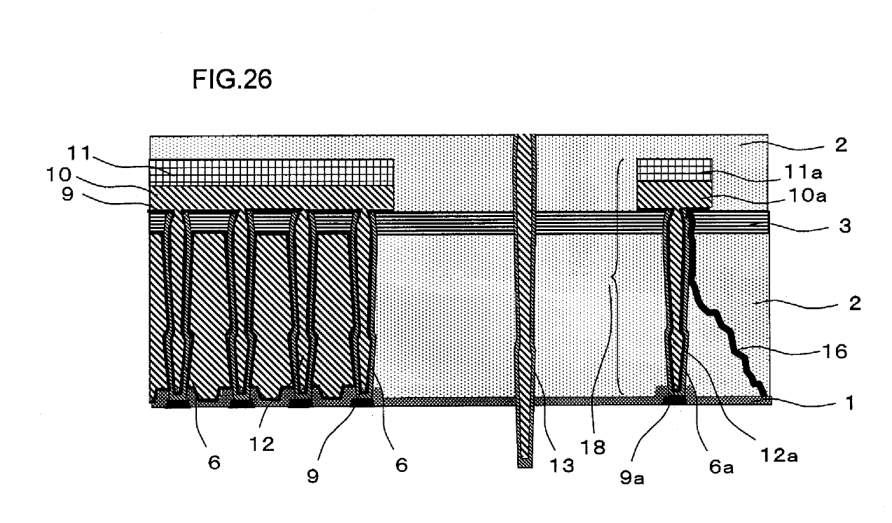

FIG. 26 is a cross-sectional view of a semiconductor chip obtained by the dicing operation. In the present exemplary embodiment, first crack stoppers 18 were formed in area at the same level as the capacitors. Upper areas 10a and 11a were provided in upper portion of each of first crack stopper 18, as shown in FIG. 26. Upper areas 10a and 11a cause crack 16 produced at the time of dicing in the vicinity of a lower portion of the first crack stopper to stop at upper regions 10a and 11a of the first crack stopper. Upper areas 10a and 11a prevent crack 16 from propagating to a region above the first crack stopper. As a result, no crack reaches the circuit portion of the semiconductor chip, and hence no destruction of the circuit portion and no degradation of the chip occur. Further, no water passes through a crack, corrodes wiring, and causes failure of the chip. The yield of the semiconductor devices can thus be improved.

In the present exemplary embodiment, the capacitors and first crack stoppers 18 can be simultaneously formed in a single step. The first crack stoppers can therefore be formed in a simple step without any increase in cost.

The shortest distance between each of the first crack stoppers and the corresponding one of the die seal rings preferably ranges from 0.5 to 5 μm. The “shortest distance between each of the first crack stoppers and the corresponding one of the die seal rings” means the shortest distance between the first crack stopper and the die seal ring in the direction perpendicular to the thickness direction of the silicon oxide film and expressed as L in FIGS. 23 and 24. Setting the shortest distance at a value ranging from 0.5 to 5 μm effectively prevents a crack from occurring and propagating.

### Second Exemplary Embodiment

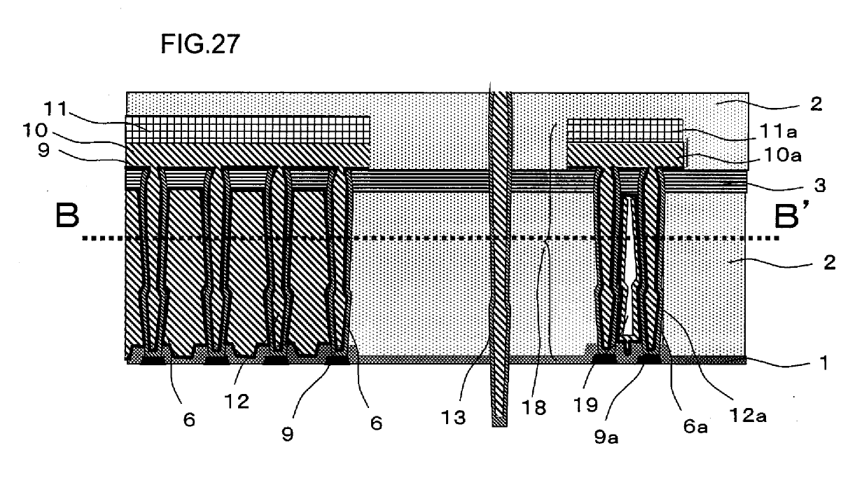

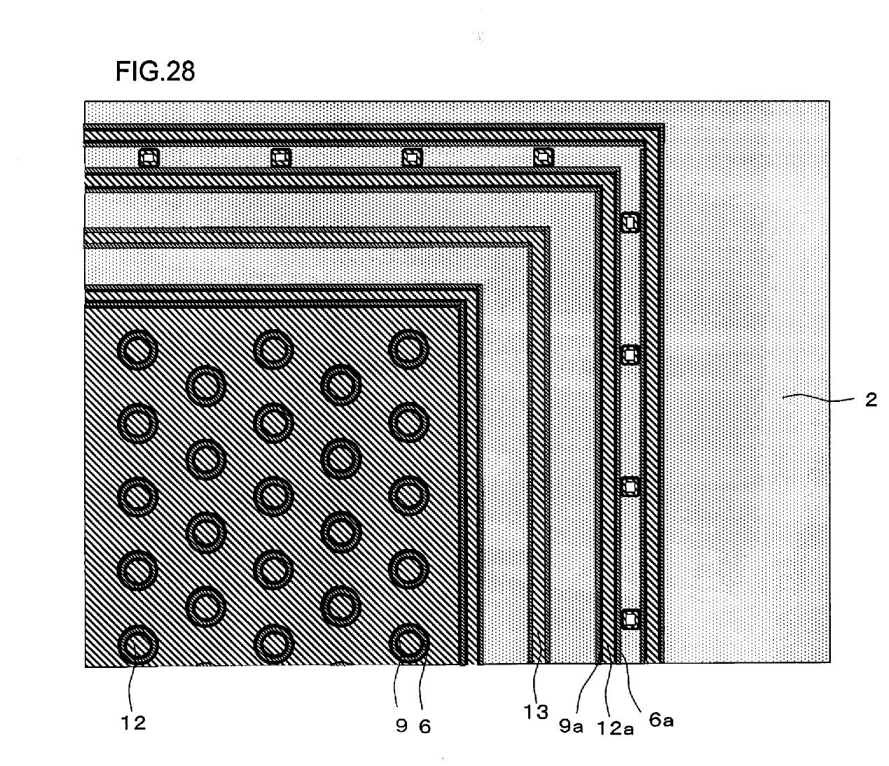

FIG. 27 is a cross-sectional view showing a semiconductor device according to the present exemplary embodiment, and FIG. 28 is a plan view taken along plane B-B′ in FIG. 27. The semiconductor device of the present exemplary embodiment differs from the first present exemplary embodiment in that each of the crack stoppers is formed of first and second crack stoppers and parts of the area between the first and second crack stoppers include cavities.

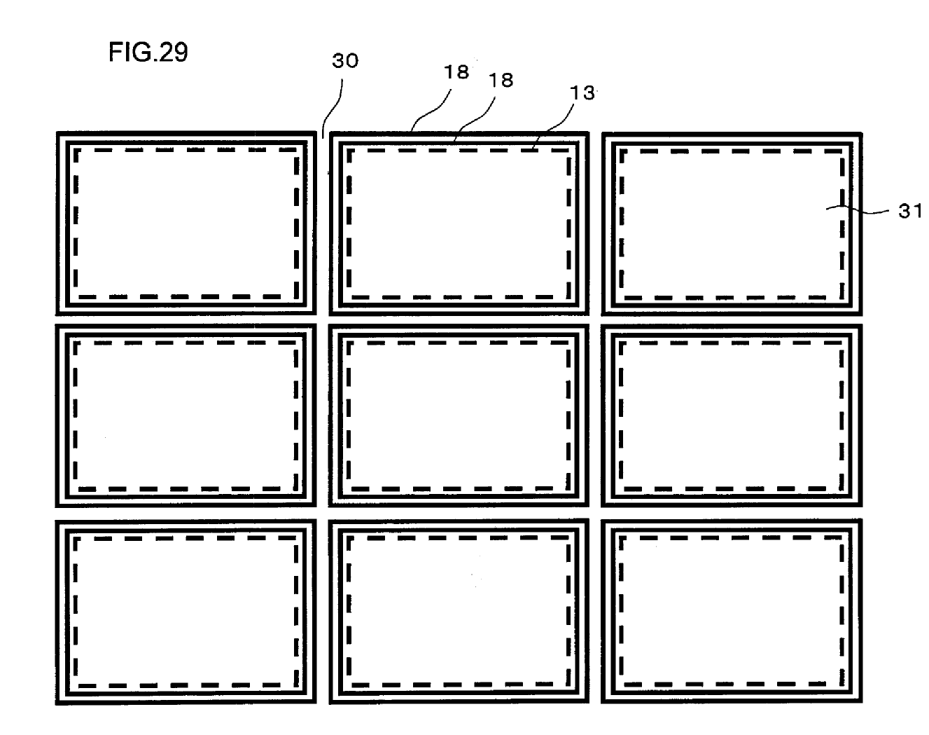

FIG. 29 shows how a wafer is diced into individual semiconductor chips. Thick lines 18 in FIG. 29 represent crack stoppers, and the portion surrounded by each of the thick lines represents a circuit area and corresponds to the first area.

In the present exemplary embodiment, each of crack stoppers 18 is formed of two crack stoppers provided in area at the same level as the capacitors. Parts of the area between the two crack stoppers form cavities 19, which make it difficult for a crack to propagate. The ability to prevent a crack from propagating to a region above crack stopper 18 can therefore be more improved than that in the first present exemplary embodiment. As a result, the yield of the semiconductor device can be further improved.

The method for manufacturing a semiconductor device according to the present exemplary embodiment will be described below with reference to the first present exemplary embodiment. The structure shown in FIG. 13 was first formed. Two openings for stopping cracks (corresponding to second and third openings) were then provided instead of forming one opening 17 for stopping cracks.

The lower electrodes were formed in the cylinder holes, and the first film was formed on the inner wall of each of the second and third openings for crack stopper at the same time.

When openings for wet etching were provided in the silicon nitride film, a plurality of openings were provided at the same time in silicon nitride film 3 on silicon oxide film 2 present between the two openings for crack stoppers. The length of one side of each of the plurality of openings is preferably 0.3 μm or smaller, and the distance between the openings preferably ranges from 0.5 to 5 μm. The distance between the two openings for crack stoppers is preferably 0.5 μm or greater. Setting the diameter of the openings and the distance between the openings for crack stoppers as described above prevents the cavities between the two crack stoppers from being completely filled with polysilicon film 10 and W film 11 when films 10 and 11 are deposited over the surface of the resulting structure in a later step.

Thereafter, wet etching was carried out by using silicon nitride film 3 as a mask to remove the silicon oxide films between the cylinder holes and between the two openings for crack stoppers. Cavities were thus formed.

Polysilicon film 10 and W film 11 were sequentially deposited over the surface of the resulting structure. In this process, the second and third films were formed in the openings for crack stoppers. Although polysilicon film 10 and W film 11 were deposited also in the cavities, but they were not completely filled with polysilicon film 10 or W film 11 and cavities 19 were left.

As described above, a structure including the crack stoppers, each of which is formed of the first and second crack stoppers, and the cavities between the first and second crack stoppers was formed.

### Third Exemplary Embodiment

The present exemplary embodiment differs from the first present exemplary embodiment in that each of the capacitors is electrically connected to one of the source and drain regions of a field effect transistor to form a DRAM (Dynamic Random Access Memory).

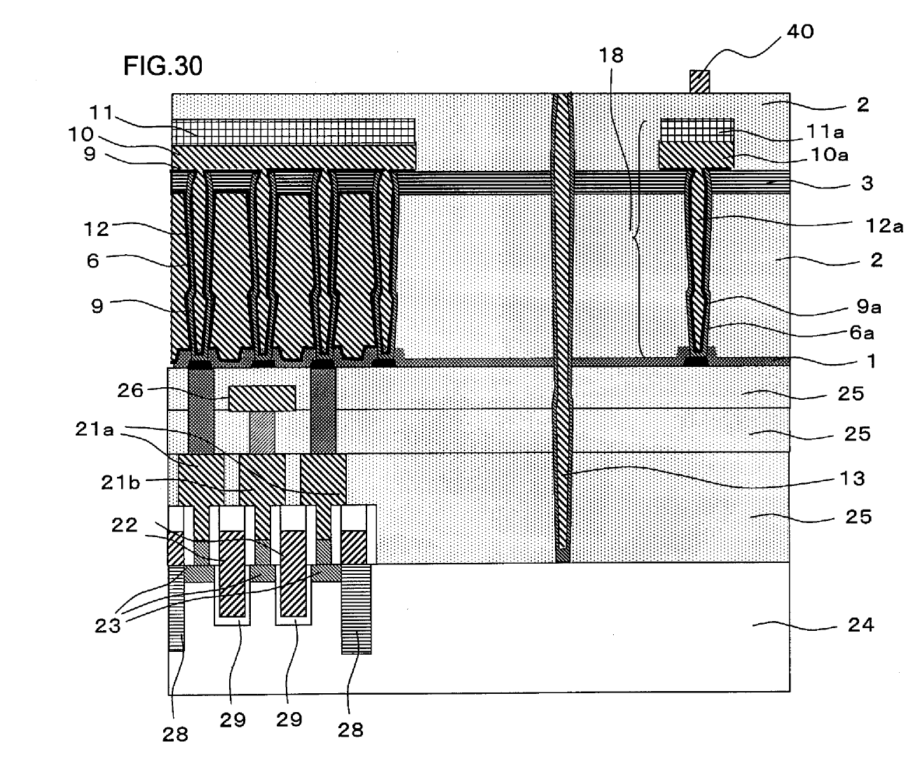

FIG. 30 is a cross-sectional view showing a semiconductor device according to the present exemplary embodiment. In FIG. 30, a wiring structure and other components to which the die seal rings are connected is omitted. As shown in FIG. 30, gate electrodes 22, gate insulating films 29, and source/drain regions 23 are formed in the area in semiconductor substrate 24 that is partitioned by isolation region 28. The area in semiconductor substrate 24 that is partitioned by isolation region 28, gate electrodes 22, gate insulating films 29, and source/drain regions 23 form field effect transistors. FIG. 30 shows two field effect transistors, which share the source region or the drain region.

Interlayer insulating film 25 is formed on semiconductor substrate 24. Bit-line contact plug 21b electrically connected to one of the source and drain regions is formed in interlayer insulating film 25. Bit-line contact plug 21b is formed by laminating tungsten (W) or any other suitable substance on a barrier film (TiN/Ti) formed of a laminate film made of titanium nitride (TiN) and titanium (Ti). Bit wiring line 26 is formed and electrically connected to bit-line contact plug 21b. Bit wiring line 26 is formed of a laminate film made of tungsten nitride (WN) and tungsten (W).

Capacitive contact plugs 21a electrically connected to the other one of the source and drain regions are formed. Capacitors electrically connected to capacitive contact plugs 21a are formed.

A single memory cell is formed of a single field effect transistor and a single capacitor and can store information by judging whether or not the capacitor holds electric charge. FIG. 30 shows two memory cells.

Further, a dummy wiring layer 40 may be formed over the crack stoppers. The dummy wiring layer is formed by using a metal film such as an aluminum film or a cupper film. If a crack is formed over the crack stoppers, the dummy wiring layer prevents the crack from penetrating into the circuit area.

In the present exemplary embodiment, the type of field effect transistor is not particularly limited. As the field effect transistor, a field effect transistor including a trench gate electrode, a planar field effect transistor, a recess-channel field effect transistor, a fin-type field effect transistor, and other field effect transistors can be used.

It is apparent that the present invention is not limited to the above embodiments, but may be modified and changed without departing from the scope and spirit of the invention.

What is claimed is:

1. A semiconductor device comprising:
an interlayer insulating film;
a first area provided in the interlayer insulating film; and
a first crack stopper provided in the interlayer insulating film and surrounding the first area,
wherein the first area includes:
a plurality of capacitors, each of the capacitors including a lower electrode and a dielectric film sequentially formed on the inner wall of a first opening passing through the interlayer insulating film in the thickness direction thereof; and
an upper electrode buried in the first opening in such a way that the upper electrode is in contact with the dielectric film, and
the first crack stopper includes:
a first film and a second film sequentially formed on the inner wall of a second opening surrounding the first area and passing through the interlayer insulating film in the thickness direction thereof; and
a third film buried in the second opening in such a way that the third film covers the second opening and is in contact with the second film,
wherein the first film is made of the same material as the lower electrode, and the second film is made of the same material as the dielectric film, and the third film is made of the same material as the upper electrode.

2. The semiconductor device according to claim 1, further comprising a die seal ring in the first area, the die seal ring surrounding the capacitors located in the first area and passing through the interlayer insulating film in the thickness direction thereof to extend to a portion above the interlayer insulating film.

3. The semiconductor device according to claim 1, further comprising:
a plate electrode provided over the interlayer insulating film in the first area and including a part of the upper electrode of each of the capacitors; and
an upper area film provided over the interlayer insulating film and including a part of the third film,
wherein the upper area film is made of the same material as the plate electrode.

4. The semiconductor device according to claim 2,
wherein the shortest distance between the first crack stopper and the die seal ring ranges from 0.5 to 5 μm.

5. The semiconductor device according to claim 1,
wherein the first area further includes:
field effect transistors, one of source and drain regions of each of the field effect transistors being electrically connected to the corresponding one of the capacitors; and
bit lines, each of the bit lines being electrically connected to the other one of the source and drain regions of the corresponding one of the field effect transistors, and
each of the capacitors and the corresponding one of the field effect transistors constitute a memory cell.

6. The semiconductor device according to claim 1, further comprising:
a second crack stopper provided substantially parallel to the first crack stopper; and
a cavity provided in the interlayer insulating film between the first and second crack stoppers,
wherein the second crack stopper includes:
the first and second films sequentially formed on the inner wall of a third opening surrounding the first crack stopper and passing through the interlayer insulating film in the thickness direction thereof; and
the third film buried in the third opening in such a way that the third film covers the third opening and is in contact with the second film.

7. The semiconductor device according to claim 1, further comprising a dummy wiring layer over the first crack stopper.

8. The semiconductor device according to claim 1, further comprising a dicing area surrounding the first area,
wherein the first crack stopper is located at a border area between the dicing area and the first area.

9. A method for manufacturing a semiconductor device, the method comprising:
preparing a wafer including an interlayer insulating film including a first area;
simultaneously forming a first opening passing through the interlayer insulating film in the first area in the thickness direction thereof, and a second opening surrounding the first area and passing through the interlayer insulating film in the thickness direction thereof;
simultaneously forming a lower electrode on the inner wall of the first opening and a first film on the inner wall of the second opening;
removing the interlayer insulating film in the first area surrounding the first opening;
simultaneously forming a dielectric film on the lower electrode in the first opening and a second film on the first film in the second opening;
simultaneously forming an upper electrode on the dielectric film and a third film on the second film, the third film covering the second opening; and
dicing the wafer at a dicing area to get a plurality of semiconductor chips,
wherein the second opening is formed at a border area between the dicing area and the first area.

10. The method for manufacturing a semiconductor device according to claim 9, further comprising forming a die seal ring in the first area before dicing the wafer, the die seal ring surrounding a capacitor located in the first area and passing through the interlayer insulating film in the thickness direction thereof to extend to a portion above the interlayer insulating film.

11. The method for manufacturing a semiconductor device according to claim 9, further comprising:
simultaneously forming a plate electrode film on the upper electrode and a fourth film on the third film before dicing the wafer; and
simultaneously forming a plate electrode and an upper area film,
wherein the plate electrode is formed by patterning the plate electrode film and the upper electrode, and the upper area film is formed by patterning the fourth film and the third film.

12. The method for manufacturing a semiconductor device according to claim 10,
wherein the shortest distance between the die seal ring and the second opening is set from 0.5 to 5 μm.

13. The method for manufacturing a semiconductor device according to claim 9, before preparing the wafer, further comprising forming a field effect transistor, a bit line electrically connected to one of source and drain regions of the field effect transistor, and a contact plug electrically connected to the other one of the source and drain regions of the field effect transistor,
wherein the lower electrode is formed so as to be connected electrically to the contact plug.

14. The method for manufacturing a semiconductor device according to claim 9,
wherein in simultaneously forming the first and second openings, a third opening is formed simultaneously with the formation of the first and second openings, the third opening surrounding the second opening and parallel thereto and passing through the interlayer insulating film in the thickness direction thereof,
in simultaneously forming the lower electrode and the first film, the first film is formed on the inner wall of the third opening simultaneously with the formation of the lower electrode and the first film,
in removing the interlayer insulating film, the interlayer insulating film between the second opening and the third opening is removed to form a cavity simultaneously with the removal of the interlayer insulating film in the first area,
in simultaneously forming the dielectric film and the second film, the second film is formed on the first film in the third opening simultaneously with the formation of the dielectric film and the second film in such a way that the cavity is left, and
in simultaneously forming the upper electrode and the third film, the third film is formed on the second film in the third opening simultaneously with the formation of the upper electrode and the third film in the second opening in such a way that the cavity is left.

15. The method for manufacturing a semiconductor device according to claim 11, further comprising forming a dummy wiring layer over the upper area film before dicing the wafer.
